(19) United States
(12) Patent Application Publication
(10) Pub. No.: US 2022/0052293 A1
(43) Pub. Date: Feb. 17, 2022

(54) DISPLAY DEVICE

(71) Applicant: SHARP KABUSHIKI KAISHA, Sakai City, Osaka (JP)

(72) Inventors: TAKESHI HIRASE, Sakai City, Osaka (JP); TOHRU SONODA, Sakai City, Osaka (JP)

(21) Appl. No.: 17/278,923

(22) PCT Filed: Sep. 26, 2018
(86) PCT No.: PCT/JP2018/035803

§ 371 Date: Mar. 23, 2021

(51) Int. Cl. H01L 51/52; H01L 27/32; H01L 51/56

(52) U.S. Cl. CPC H01L 51/5253; H01L 27/3258; H01L 27/1225; H01L 51/56; H01L 27/3262

(57) ABSTRACT

A display device includes: a display region including a TFT layer provided with a plurality of transistors, a light-emitting element layer provided with a plurality of light-emitting elements, and a sealing layer; and a frame region surrounding the display region. The light-emitting element includes a first electrode, an edge cover provided with an opening that exposes the first electrode and configured to cover an end portion of the first electrode, a function layer, and a second electrode. A first hydrogen adsorption film is provided at an upper layer overlying the edge cover and in contact with the edge cover. The first hydrogen adsorption film overlaps the transistor, at the adjacent light-emitting element. The first hydrogen adsorption film is provided overlapping the first electrode of the adjacent light-emitting element, with the edge cover interposed therebetween, and spanning the adjacent light-emitting element.

### TECHNICAL FIELD

The present invention relates to a display device.

### BACKGROUND ART

In a display device, when hydrogen desorption occurs from a layer from which hydrogen is easily desorbed, such as a layer formed by CVD, and the hydrogen penetrates a transistor and the like in a TFT layer, a shift in characteristics, such as a Vth shift in the transistor, occurs. This causes various display defects, such as an abnormality in gray scale display. To prevent such problems, techniques for providing a hydrogen adsorption film have been developed.

In PTL 1, an organic semiconductor device is disclosed that is formed by layering at least a substrate, a first electrode, an organic functional body, and a second electrode in this order. On the second electrode, a hydrogen adsorption layer is provided that adsorbs hydrogen or hydrogen ions and that does not release the absorbed hydrogen or hydrogen ions.

In PTL 2, a display device is disclosed that includes an oxide semiconductor layer that forms a channel, a first layer that has insulating or conductive properties, and a second layer that contains a hydrogen adsorbent and is provided between the oxide semiconductor layer and the first layer.

In PTL 3, an organic electroluminescent light-emitting element is disclosed that includes a first substrate, a thin film transistor on the first substrate, a flattening layer on the thin film transistor, an organic light-emitting diode on the flattening layer, a passivation layer on the organic light-emitting diode, a second substrate on the passivation layer, and a hydrogen adsorbing substance between the first substrate and the second substrate. The hydrogen adsorbing substance causes hydrogen to dissociate, in order to prevent oxidation of a substance constituting the thin film transistor.

### CITATION LIST

### Patent Literature

PTL 1: WO2009/004690
PTL 2: JP 2015-36797 A
PTL 3: JP 2015-79755 A

### SUMMARY OF INVENTION

### Technical Problem

However, in the conventional display devices, hydrogen cannot be favorably adsorbed without impairing optical transparency.

### Solution to Problem

In order to solve the problem described above, a display device according to the present invention includes a display region including a TFT layer provided with a plurality of transistors, a light-emitting element layer provided with a plurality of light-emitting elements, and a sealing layer, and a frame region surrounding the display region. The light-emitting element includes a first electrode, an edge cover provided with an opening that exposes the first electrode and configured to cover an end portion of the first electrode, a function layer, and a second electrode. The first hydrogen adsorption film is provided at an upper layer overlying the edge cover and in contact with the edge cover, and the first hydrogen adsorption film overlaps the transistor, at the adjacent light-emitting element, and is provided overlapping the first electrode of the adjacent light-emitting element, with the edge cover interposed therebetween, and spanning the adjacent light-emitting element.

### Advantageous Effects of Invention

According to an aspect of the present invention, hydrogen can be favorably adsorbed without impairing optical transparency.

### BRIEF DESCRIPTION OF DRAWINGS

FIG. 1 is a schematic cross-sectional view of a display device according to a first embodiment of the present invention.

FIG. 2 is a schematic top view of the display device according to the first embodiment of the present invention.

FIG. 3 is a diagram illustrating an example of a subpixel circuit of the display device according to the first embodiment of the present invention.

FIG. 4 is an enlarged top view of a display region of the display device according to the first embodiment of the present invention.

FIG. 5 is a flowchart for describing a manufacturing method for the display device according to the first embodiment of the present invention.

FIG. 6 is an enlarged top view of the display region of the display device according to a second embodiment of the present invention.

FIG. 7 is an enlarged top view of the display region of the display device according to a third embodiment of the present invention.

### DESCRIPTION OF EMBODIMENTS

In the following, the “same layer” means being formed of the same material in the same process. In addition, “lower layer” means a layer that is formed in a process prior to that of a comparison layer, and “upper layer” means a layer that is formed in a process after that of a comparison layer. In this specification, a direction from a lower layer to an upper layer of a display device will be described as an upward direction.

### First Embodiment

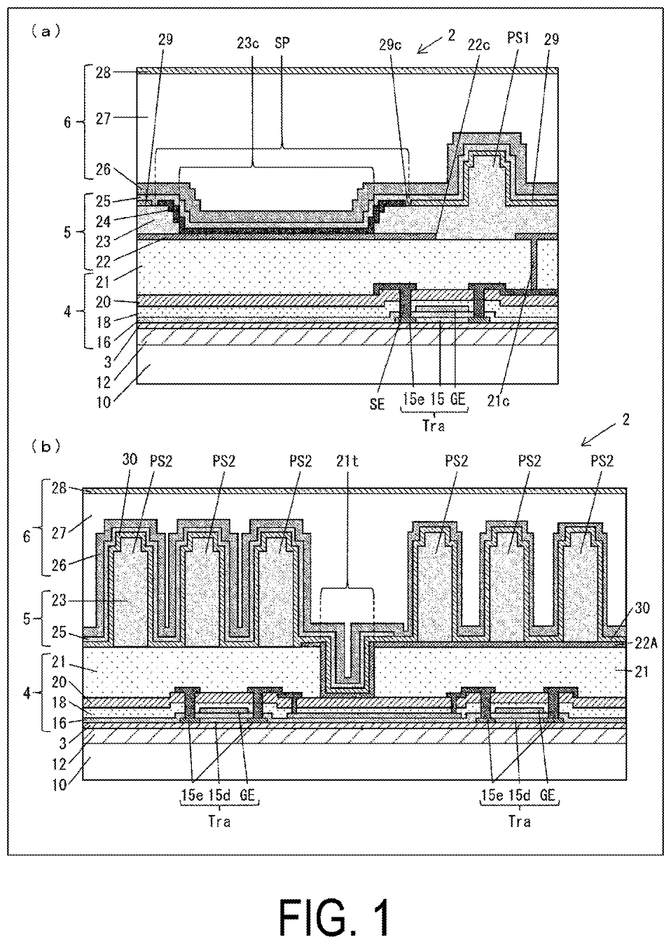

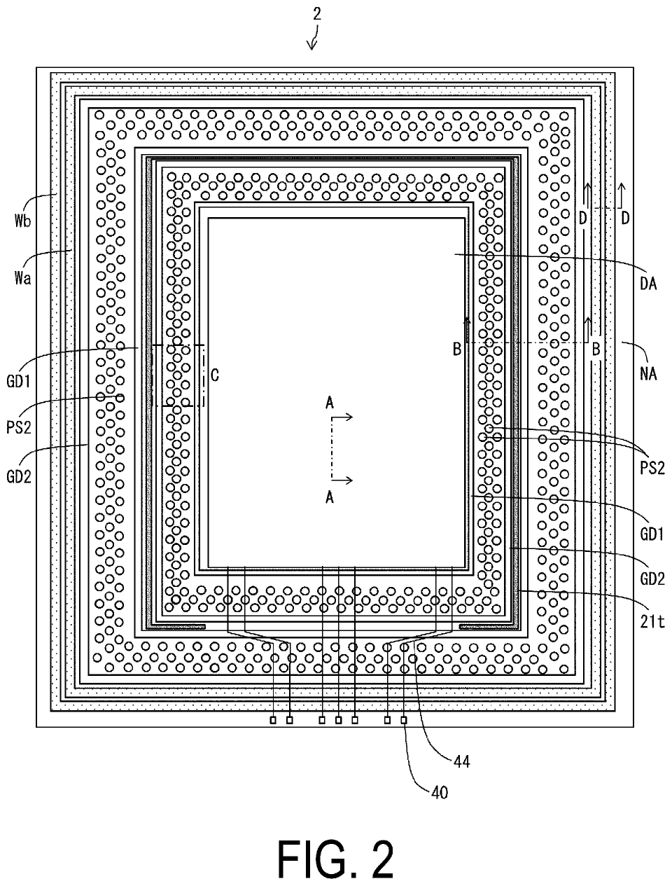

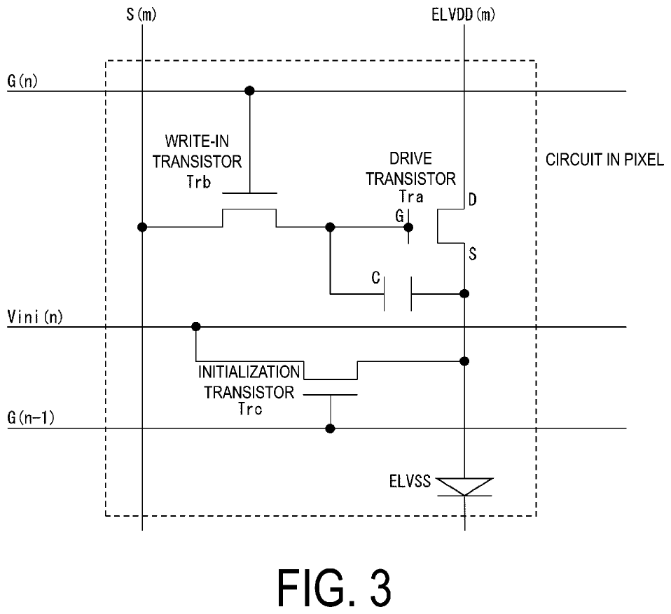

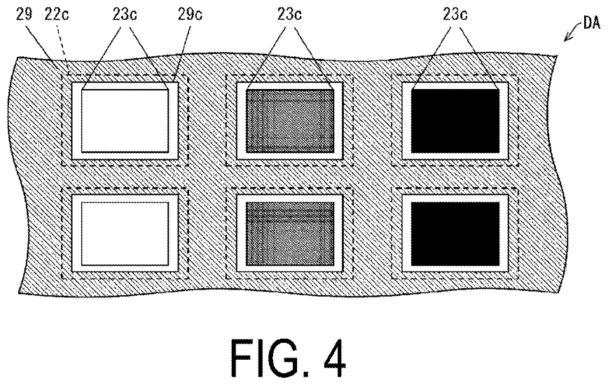

FIG. 2 is a top view of a display device 2 according to a first embodiment of the present invention. FIG. 1 is a schematic cross-sectional view of the display device 2 according to the first embodiment of the present invention. (a) of FIG. 1 is a cross-sectional view viewed in a direction of arrows along a line A-A in FIG. 2, and (b) of FIG. 1 is a cross-sectional view viewed in a direction of arrows along a line B-B in FIG. 2. FIG. 3 is a diagram illustrating an example of a subpixel circuit of the display device 2 according to the first embodiment of the present invention. FIG. 4 is an enlarged top view of a display region DA of the display device 2 according to the first embodiment of the present invention. Specifically, FIG. 4 is also an enlarged view of the display region DA in FIG. 2. Note that illustration of a second electrode 25 and a sealing layer 6, which will be described later in detail, is omitted in FIG. 2. Further, in (b) of FIG. 1, the left side, when viewed in a direction toward the paper surface, is the display region DA side.

As illustrated in FIG. 2, the display device 2 according to the present embodiment includes the display region DA and a frame region NA provided adjacent to and around the display region DA. The display device 2 according to the present embodiment will be described in detail with reference to (a) and (b) of FIG. 1.

As illustrated in (a) and (b) of FIG. 1, the display device 2 according to the present embodiment includes a support substrate 10, a resin layer 12, a barrier layer 3, a TFT layer 4, a light-emitting element layer 5, and a sealing layer 6 in this order from the lower layer side. Further, in a further upper layer overlying the sealing layer 6, the display device 2 may be provided with a function film or the like having an optical compensation function, a touch sensor function, a protection function, and the like.

The support substrate 10 may be, for example, a glass substrate. For example, the support substrate 10 may be a glass substrate obtained by dicing a large mother glass substrate when manufacturing the display device 2. The material of the resin layer 12 may be, for example, polyimide.

The barrier layer 3 is a layer that prevents water, oxygen and the like from penetrating the TFT layer 4 and the light-emitting element layer 5 when the display device 2 is used. The barrier layer 3 can be constituted by a silicon oxide film, a silicon nitride film, or a silicon oxynitride film, or a layered film formed by layering these films, formed by CVD, for example.

The TFT layer 4 includes semiconductor layers 15 and 15d, a plurality of thin film transistors (transistors) Tr, a first inorganic layer 16 (a gate insulating film), a gate electrode GE, a second inorganic layer 18, a third inorganic layer 20, a source wiring line SH (a metal wiring line layer), and a flattening film 21 (an interlayer insulating film) in this order from the lower layer side. The semiconductor layers 15 and 15d and the source wiring line SH are electrically connected to each other at a semiconductor electrode 15e. The transistor Tr is configured to include the semiconductor layers 15 and 15b, the first inorganic layer 16, and the gate electrode GE.

Here, the transistor Tr (a drive transistor Tra, for example), which includes the semiconductor layers 15 and 15d, and is protected by a first hydrogen adsorption film 29 and a second hydrogen adsorption film 30, is formed using an oxide semiconductor (an In—Ga—Zn—O-based semiconductor, for example) or the like. Although the TFT having the semiconductor layers 15 and 15b as channels and having a top gate structure is illustrated in FIG. 1, the TFT may have a bottom gate structure (for example, in a case where the channel of the TFT is an oxide semiconductor). The gate electrode GE or the source wiring line SH may include, for example, at least one of aluminum (Al), tungsten (W), molybdenum (Mo), tantalum (Ta), chromium (Cr), titanium (Ti), and copper (Cu). Specifically, the gate electrode GE or the source wiring line SH is constituted by a single-layer film or a layered film of any of the metals described above. Note that a write transistor Trb or the like, which is not protected by the first hydrogen adsorption film 29 and the second hydrogen adsorption film 30, may be formed using, for example, an In—Ga—Zn—O-based semiconductor, or may be formed using low-temperature polysilicon (LTPS).

The first inorganic layer 16, the second inorganic layer 18, and the third inorganic layer 20 can be formed by a silicon oxide (SiOx) film, a silicon nitride (SiNx) film, or a layered film thereof, formed by CVD, for example.

The flattening film 21 can be constituted by a coatable photosensitive organic material such as polyimide or acryl. In the present embodiment, as illustrated in (b) of FIG. 1, in the frame region NA, the flattening film 21 has an opening, and a trench 21t is formed in the opening of the flattening film 21 so as to surround the display region DA. As illustrated in FIG. 2, the trench 21t may be formed so as to surround the display region DA along three sides of the display device 2, excluding a side facing terminal portions 40. Further, the trench 21t may also be formed in a portion, such as portions near both ends, of the side facing the terminal portions 40.

The light-emitting element layer 5 (an organic light-emitting diode layer, for example) includes the first electrode 22 (an anode, for example) that is an upper layer overlying the flattening film 21, an edge cover 23 that covers the first electrode 22, a function layer 24, the second electrode (a cathode, for example) 25, the first hydrogen adsorption film 29 that overlaps the first electrode 22 and the edge cover 23, and the second hydrogen adsorption film 30 that overlaps the second electrode 25 and the edge cover 23. As a result, the first hydrogen adsorption film 29 and the second hydrogen adsorption film 30 can favorably adsorb hydrogen desorbed from a first inorganic sealing film 26 and a second inorganic sealing film 28 included in the sealing layer 6.

In the light-emitting element layer 5, for each of subpixels SP (pixels), the island-shaped first electrode 22, and an opening that exposes the first electrode 22 are provided, and further, for each of the subpixels SP, a plurality of light-emitting elements (OLEDs: organic light-emitting diodes, for example) that include the edge cover 23 covering an end portion of the first electrode 22, the island-shaped function layer 24, and the second electrode 25, and a subpixel circuit that drives each of the subpixels are provided. Further, in the TFT layer 4, the transistor Tr is formed for each of the subpixel circuits, and the subpixel circuit is controlled under the control of the transistor Tr. Note that. in the frame region NA, a GDM circuit is formed in the TFT layer 4, and the drive transistor Tra for driving a gate driver is formed in the frame region NA.

The subpixel circuit will be described below in detail with reference to FIG. 3. As illustrated in FIG. 3, the transistors Tr, such as the drive transistor Tra, the write transistor Trb, and an initialization transistor Trc, and a capacitor C are formed in the subpixel circuit. Further, a control terminal of the drive transistor Tra is connected to one of conduction terminals of the write transistor Trb and to one of electrodes of the capacitor C. A drain electrode of the drive transistor Tra is connected to a high power supply voltage ELVDD(m). A source electrode is connected to the other electrode of the capacitor C, the first electrode 22, and one of conduction terminals of the initialization transistor Trc. A control terminal of the write transistor Trb is connected to a gate wiring line G(n), and the other conduction terminal of the write transistor Trb is connected to a source wiring line S(m). A control terminal of the initialization transistor Trc is connected to a gate wiring line G(n−1), and the other conduction terminal of the initialization transistor Trc is connected to an initialization wiring line Vini(n).

Note that the subpixel circuit described above is an example, and the present embodiment is not limited thereto.

In a plan view, the first electrode 22 is provided in a position overlapping the flattening film 21 and a contact hole 21c, which is an opening of the flattening film 21. The first electrode 22 is electrically connected to the source wiring line SH via the contact hole 21c. Thus, a signal in the TFT layer 4 is supplied to the first electrode 22 via the source wiring line SH. Note that the thickness of the first electrode 22 may be 100 nm, for example.

The first electrode 22 is formed in an island shape for each of the plurality of subpixels SP, is constituted, for example, by layering indium tin oxide (ITO) and an alloy containing Ag, and has light reflectivity. The second electrode 25 is formed in a solid-like state as a common layer for the plurality of subpixels SP, and can be constituted by a transparent conductive material such as indium tin oxide (ITO) or indium zinc oxide (IZO). As illustrated in (b) of FIG. 1, in the trench 21t of the frame region NA, a conductive film 22A is formed that is formed of the same material in the same layer as the first electrode 22, and the conductive film 22A is electrically connected to the second electrode 25 via the second hydrogen adsorption film 30. Here, when the first electrode 22 is directly electrically connected to the second electrode 25, a short circuit occurs and the light-emitting element does not emit light. In contrast, as described above, by interposing the second hydrogen adsorption film 30 between the first electrode 22 and the second electrode 25, the conductive film 22A formed of the same material in the same layer as the first electrode 22 can be connected to an ELVSS terminal in the second electrode 25 without causing a short circuit.

The edge cover 23 is an organic insulating film, is formed in a position covering an edge 22c of the first electrode 22, and includes an opening 23c for each of the plurality of subpixels SP, thus exposing a portion of the first electrode 22.

As illustrated in (a) of FIG. 1, the display device 2 according to the present embodiment includes first photospacers PS1 in the display region DA. Further, as illustrated in (b) of FIG. 1, the display device 2 includes second photospacers PS2 in the frame region NA. In the present embodiment, the first photospacers PS1 and the second photospacers PS2 are formed in an upper layer overlying the flattening film 21. Furthermore, the first photospacers PS1 and the second photospacers PS2 are formed in the same layer as the edge cover 23, and formed of the same material as the edge cover 23. Thus, the edge cover 23, the first photospacers PS1, and the second photospacers PS2 can be manufactured by the same process.

As illustrated in (b) of FIG. 1, the second photospacers PS2 are formed in positions overlapping the conductive film 22A.

The function layer 24 is formed, for example, by layering a hole transport layer, a light-emitting layer, and an electron transport layer in this order from the lower layer side. In the present embodiment, at least one of the layers of the function layer 24 is formed by vapor deposition. Further, in the present embodiment, each of the layers of the function layer 24 may be formed in an island shape for each of the subpixels SP, or may be formed in a solid-like state as a common layer for the plurality of subpixels SP.

When the light-emitting element layer 5 is an OLED layer, positive holes and electrons are recombined in the function layer 24 by a drive current between the first electrode 22 and the second electrode 25 to generate excitons, and the excitons then fall to a ground state to emit light. Because the second electrode 25 is transparent and the first electrode 22 has light reflectivity, the light emitted from the function layer 24 is directed upward to configure a top-emitting structure.

The first hydrogen adsorption film 29 is provided in contact with the edge cover 23 in an upper layer overlying the edge cover 23. Further, the first hydrogen adsorption film 29 is provided so as to span adjacent light-emitting elements, by overlapping the transistor Tr (the drive transistor Tra, for example) in the adjacent light-emitting elements, and overlapping the first electrodes 22 in the adjacent light-emitting elements with the edge cover 23 interposed therebetween. As illustrated in FIG. 4, the first hydrogen adsorption film 29 is formed so as to span at least the adjacent light-emitting elements of the same color. As a result, even when the first hydrogen adsorption film 29 is constituted by a hydrogen adsorption metal and is opaque, it is possible to prevent optical transparency of the display device 2 from being impaired, without inhibiting light transmitted from the opening 23c of the edge cover 23.

Further, the first hydrogen adsorption film 29 is formed to include an opening 29c between the opening 23c of the edge cover 23 and the edge 22c of the first electrode 22. Specifically, as illustrated in (a) of FIG. 1 and FIG. 4, the first hydrogen adsorption film 29 includes the opening 29c, which is smaller than the edge 22c of the first electrode 22 and is larger than the opening 23c (specifically, a light-emitting region in each of the subpixels (the light-emitting elements)) of the edge cover 23. Specifically, the first hydrogen adsorption film 29 is formed so as not to overlap the opening 23c of the edge cover 23, which defines the light-emitting region of each of the subpixels (the light-emitting elements). As a result, even when the first hydrogen adsorption film 29 is constituted by a hydrogen adsorption metal and is opaque, it is possible to prevent the optical transparency of the display device 2 from being impaired, without inhibiting the light transmitted from the opening 23c of the edge cover 23. Further, because the opening 29c of the first hydrogen adsorption film 29 is formed so as to be larger than the opening 23c of the edge cover 23, a short circuit can be reliably prevented.

Further, as illustrated in (a) of FIG. 1, the first hydrogen adsorption film 29 is formed on the first photospacers PS1 in the display region DA. Note that in FIG. 4, colors of the light-emitting elements in the openings 23c of the edge cover 23 are different colors, for example, red, green, and blue, respectively, in this order from the left. As illustrated in FIG. 4, the first hydrogen adsorption film 29 has the opening 29c that is larger than the opening 23c of the edge cover 23, and is formed so as to span (pass over) at least the adjacent light-emitting element of the same color. Thus, it is possible to prevent the light-emitting element from short circuiting at least with the adjacent light-emitting element of the same color.

In the frame region NA, the second hydrogen adsorption film 30 surrounds the display region DA, is formed so as to overlap the second electrode 25, and is electrically connected to the second electrode 25. As a result, the second hydrogen adsorption film 30 can be favorably connected to the second electrode 25 without being electrically connected to the first hydrogen adsorption film 29 in the display region DA.

In this way, the first hydrogen adsorption film 29 is formed in the light-emitting element layer 5 that is an upper layer overlying the TFT layer 4 including the drive transistors Tra. Further, the first hydrogen adsorption film 29 is formed in a non-light-emitting portion (a non-light-emitting area) so as to span (pass over) the light-emitting elements. Thus, the first hydrogen adsorption film 29 can favorably adsorb hydrogen desorbed (released) from the first inorganic sealing film 26 and the second inorganic sealing film 28 of the sealing layer 6 formed by CVD, without inhibiting the light transmitted from the light-emitting elements. In other words, hydrogen can be favorably adsorbed without impairing the optical transparency of the display device 2. As a result, it is possible to inhibit hydrogen from flowing into the drive transistor Tra and the like in the TFT layer 4, and to prevent an occurrence of a shift in characteristics, such as a Vth shift in the drive transistor Tra.

Further, as illustrated in (b) of FIG. 1, the second hydrogen adsorption film 30 is formed so as to overlap the second photospacers PS2 around the frame region NA. Further, in the frame region NA illustrated in (b) of FIG. 1, a control circuit (GDM) of the transistor Tr, which controls a sub-circuit, is formed so as to overlap the second hydrogen adsorption film 30. As a result, it is possible to favorably inhibit hydrogen released from the first inorganic sealing film 26 and the second inorganic sealing film 28 of the sealing layer 6 from flowing into the control circuit (GDM).

Further, as illustrated in (b) of FIG. 1, the second hydrogen adsorption film 30 can be formed in a solid-like state at a location where the function layer 24 is not formed (on a light emission control line in the trench 21t that is in an upper layer overlying the drive transistors Tra, for example), and by connecting the second hydrogen adsorption film 30 to the second electrode 25, resistance of the second electrode 25 can also be reduced.

The first hydrogen adsorption film 29 and the second hydrogen adsorption film 30 are, for example, films each including a hydrogen adsorption metal, and are preferably formed by a hydrogen adsorption metal. As a result of the first hydrogen adsorption film 29 and the second hydrogen adsorption film 30 being formed by the hydrogen adsorption metal, the first hydrogen adsorption film 29 and the second hydrogen adsorption film 30 can absorb hydrogen more favorably, for example, compared to a case where the first hydrogen adsorption film 29 and the second hydrogen adsorption film 30 include a substance other than the hydrogen adsorption metal such as a gas or the like, and a case where the first hydrogen adsorption film 29 and the second hydrogen adsorption film 30 are formed by a hydrogen adsorption alloy or the like. Examples of the hydrogen adsorption metal include Ti, Zr, Pd, Mg, and the like, each of which has excellent hydrogen adsorption capabilities and readily reacts with hydrogen to form a hydride. Each of the first hydrogen adsorption film 29 and the second hydrogen adsorption film 30 is preferably one of these hydrogen adsorption metals. As a result of each of the first hydrogen adsorption film 29 and the second hydrogen adsorption film 30 being one of these hydrogen adsorption metals, the first hydrogen adsorption film 29 and the second hydrogen adsorption film 30 can absorb hydrogen more favorably.

The thickness of each of the first hydrogen adsorption film 29 and the second hydrogen adsorption film 30 may be, for example, from 100 nm to 200 nm. According to the display device 2 of the present embodiment, since the first hydrogen adsorption film 29 and the second hydrogen adsorption film 30 are constituted by an opaque material such as a hydrogen adsorption metal, even when the first hydrogen adsorption film 29 and the second hydrogen adsorption film 30 are not thin films, it is possible to favorably absorb hydrogen without impairing the optical transparency of the display device 2.

Here, when the first hydrogen adsorption film 29 and the second hydrogen adsorption film 30 are opaque, the first hydrogen adsorption film 29 and the second hydrogen adsorption film 30 also function as light blocking films. As a result of the first hydrogen adsorption film 29 and the second hydrogen adsorption film 30 functioning as the opaque light blocking films, it is possible to prevent light from the outside of the display device 2 from being incident on the edge cover 23 or the like, which is formed by an organic material in a lower layer underlying at least one of the first hydrogen adsorption film 29 and the second hydrogen adsorption film 30. As a result, it is possible to prevent an organic layer, such as the edge cover 23, from deteriorating due to ultraviolet radiation of light. Further, as a result of the first hydrogen adsorption film 29 and the second hydrogen adsorption film 30 functioning as the opaque light blocking films, it is possible to prevent the light from the outside of the display device 2 from being incident on the drive transistor Tra or the like. As a result, it is possible to prevent the incident light from causing the drive transistor Tra to generate photovoltaic power.

Further, by forming each of the first hydrogen adsorption film 29 and the second hydrogen adsorption film 30 in an upper layer overlying the drive transistor Tra, it is possible to prevent hydrogen from penetrating the drive transistor Tra or the like. As a result, adverse effects, such as a specific shift in the drive transistor Tra, can be favorably prevented.

Further, by forming the first hydrogen adsorption film 29 and the second hydrogen adsorption film 30 so as to overlap the first photospacers PS1 and the second photospacers PS2, as illustrated in (a) and (b) of FIG. 1, when the function layer 24 is vapor-deposited, a vapor deposition mask (not illustrated) comes into contact with the first photospacers PS1 and the second photospacers PS2, and it is thus possible to prevent foreign matter from being generated from the first photospacers PS1 and the second photospacers PS2.

Note that in the display region DA, the first hydrogen adsorption film 29 is not electrically connected to a wiring line in the TFT layer 4. Further, the first hydrogen adsorption film 29 and the second hydrogen adsorption film 30 are not electrically connected with each other.

The sealing layer 6 includes the first inorganic sealing film 26 that is an upper layer overlying the second electrode 25, an organic sealing film 27 that is an upper layer overlying the first inorganic sealing film 26, and the second inorganic sealing film 28 that is an upper layer overlying the organic sealing film 27. The sealing layer 6 prevents the penetration of water, oxygen, and the like into the light-emitting element layer 5. Each of the first inorganic sealing film 26 and the second inorganic sealing film 28 may be constituted, for example, by a silicon oxide film, a silicon nitride film, or a silicon oxynitride film, or a layered film thereof, formed by CVD. The organic sealing film 27 can be constituted by a coatable photosensitive organic material such as polyimide or acrylic. The terminal portions 40 are formed in one end portion of the frame region NA. A driver (not illustrated) that supplies a signal for driving each of the light-emitting elements in the display region DA via a lead wiring line 44, and the like are mounted on the terminal portion 40.

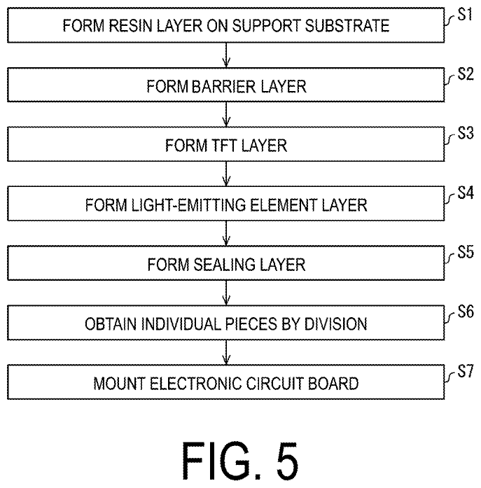

Next, a manufacturing method for the display device 2 according to the first embodiment of the present invention will be described in detail with reference to a flowchart in FIG. 5. FIG. 5 is a flowchart for describing the manufacturing method for the display device 2 according to the first embodiment of the present invention.

First, the resin layer 12 is formed on a transparent support substrate (a mother glass substrate, for example) 10 (step S1). Next, the barrier layer 3 is formed in an upper layer overlying the resin layer 12 (step S2).

Next, the TFT layer 4 is formed in an upper layer overlying the barrier layer 3 (step S3). At step S3, first, on top of the barrier layer 3, the semiconductor layer 15, the first inorganic layer 16, the gate electrode GE, the second inorganic layer 18, the third inorganic layer 20, and the source wiring line SH are formed in this order from the lower layer side. At this time, the terminal portion 40 and the lead wiring line 44 connected to the terminal portion 40 may also be formed simultaneously. When forming each of these layers, a conventional film formation method can be employed. Here, by forming, for example, the In—Ga—Zn—O-based semiconductor layer 15 at a different film forming temperature from that of the sealing layer 6, it is possible to make it difficult for hydrogen to be desorbed from the semiconductor layer 15.

Next, the flattening film 21 is formed. At this time, the flattening film 21 may be formed of a photosensitive resin using photolithography, and at the same time, the contact hole 21c, the trench 21t, and the flattening film 21 in a second bank Wb may be formed.

Next, the top-emitting type light-emitting element layer (an OLED element layer, for example) 5 is formed (step S4). First, the first electrode 22 is formed in a position including the contact hole 21c.

Next, the edge cover 23 is formed together with the first photospacers PS1 and the second photospacers PS2. Next, the first hydrogen adsorption film 29 and the second hydrogen adsorption film 30 are formed so as to overlap the first photospacers PS1 and the second photospacers PS2, respectively. The first hydrogen adsorption film 29 and the second hydrogen adsorption film 30 can be formed as a film, for example, using sputtering or a photolithography technique, and after that, can be favorably formed in a solid-like state by patterning.

Next, the function layer 24 is formed. In the present embodiment, each of the layers of the function layer 24 is formed by vapor deposition. Next, after this, by forming the second electrode 25, the plurality of subpixels SP are formed, and formation of the light-emitting element layer 5 is completed.

Here, in the present embodiment, the second photospacers PS2 on the display region DA side of the trench 21t, that is, on the left side of the trench 21t when viewed in a direction toward the paper surface in (b) of FIG. 1, may be the photospacers with which the vapor deposition mask (not illustrated) comes into contact when forming the function layer 24. Further, in the present embodiment, the second photospacers PS2 further on the frame region NA side than the trench 21t, that is, on the right side of the trench 21t when viewed in the direction toward the paper surface in (b) of FIG. 1, may be the photospacers with which the vapor deposition mask comes into contact when forming the second electrode 25.

Next, the sealing layer 6 is formed (step S5). Next, a layered body including the support substrate 10, the resin layer 12, the barrier layer 3, the TFT layer 4, the light-emitting element layer 5, and the sealing layer 6 is divided to obtain a plurality of individual pieces (step S6). Next, an electronic circuit board (an IC chip, for example) is mounted on the terminal portion 40 to configure the display device 2 (step S7).

Note that, in the present embodiment, the manufacturing method for the display device 2 including the rigid support substrate 10 is described. However, by adding some steps, the flexible display device 2 can be manufactured. For example, after step S5, a bonding force between the support substrate 10 and the resin layer 12 is reduced by irradiating the lower face of the resin layer 12 with laser light over the support substrate 10, and the support substrate 10 is peeled off from the resin layer 12. Next, a lower face film is bonded to the lower face of the resin layer 12. After that, the processing proceeds to step S6, and then, the flexible display device 2 can be obtained.

### Second Embodiment

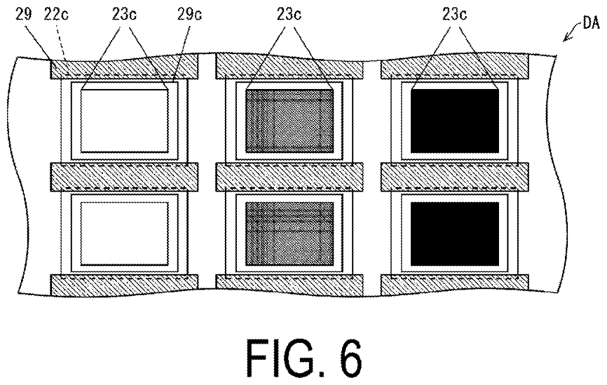

Next, with reference to FIG. 6, the display device 2 according to a second embodiment of the present invention will be described. FIG. 6 is an enlarged top view of the display region DA of the display device 2 according to the second embodiment of the present invention. The display device 2 according to the present embodiment differs from the display device 2 according to the first embodiment only in the position at which the first hydrogen adsorption film 29 is formed.

As illustrated in FIG. 6, in the display region DA of the display device 2, the first hydrogen adsorption film 29 is formed extending between two of the adjacent light-emitting elements (subpixels) of the same color. Specifically, as illustrated in FIG. 6, the first hydrogen adsorption film 29 is formed so as to overlap the edge 22c of the first electrode 22 and so as not to overlap the opening 23c of the edge cover 23. As a result, even when the first hydrogen adsorption film 29 is constituted by a hydrogen adsorption metal and is opaque, it is possible to prevent the optical transparency of the display device 2 from being impaired, without inhibiting the light transmitted from the opening 23c of the edge cover 23.

Further, in FIG. 6, the first hydrogen adsorption film 29 is formed so as to span the adjacent light-emitting element of a different color. In this way, a short circuit can be reliably prevented. In FIG. 6, as a lower layer underlying the first hydrogen adsorption film 29, the TFT layers 4 of two subpixels of the same color are formed. As a result, it is possible to prevent hydrogen from flowing into the drive transistor Tra in each of the TFT layers 4 provided in the two subpixels.

Further, as illustrated in FIG. 6, the first hydrogen adsorption film 29 may be formed in an island shape for each of the two adjacent light-emitting elements of the same color. As a result, a short circuit can be more favorably prevented.

### Third Embodiment

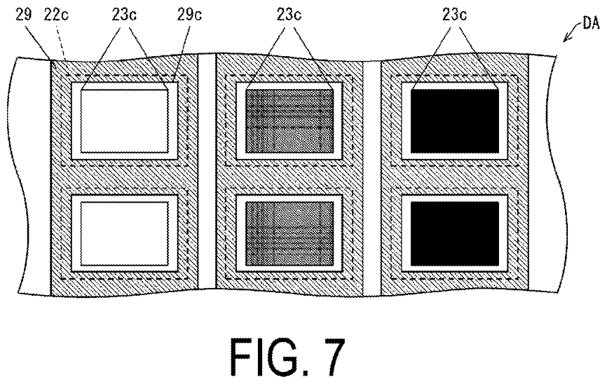

Next, the display device 2 according to a third embodiment of the present invention will be described with reference to FIG. 7. FIG. 7 is an enlarged top view of the display region DA of the display device 2 according to the third embodiment of the present invention. The display device 2 according to the present embodiment differs from the display device 2 according to the first embodiment only in that the first hydrogen adsorption film 29 is additionally formed.

As illustrated in FIG. 7, in the display device 2 according to the present embodiment, the first hydrogen adsorption film 29 is formed in a straight line with respect to the light-emitting elements of each of the different colors in the display region DA. Specifically, as illustrated in FIG. 6, the first hydrogen adsorption film 29 is formed in the straight line so as to overlap the edge 22c of the first electrode 22 and so as not to overlap the opening 23c of the edge cover 23. By forming the first hydrogen absorption film 29 in the straight line for the light-emitting elements of each of the different colors in this manner, it is possible to favorably absorb hydrogen generated in the first inorganic sealing film 26 and the second inorganic sealing film 28 of the sealing layer 6 between the light-emitting elements of different colors, while preventing the short circuit.

Further, the display device 2 according to each of the embodiments described above may include an organic light-emitting diode (OLED) as a current-controlled display element. In this case, the display device 2 according to each of the above-described embodiments may be an organic electro luminescence (EL) display.

Alternatively, the display device 2 according to each of the above-described embodiments may include an inorganic light-emitting diode as the current-controlled display element. In this case, the display device 2 according to each of the above-described embodiments may be a quantum dot light-emitting diode (QLED) display provided with EL display QLEDs, such as an inorganic EL display.

Further, examples of a voltage-controlled display element include a liquid crystal display element and the like.

### Supplement

A display device according to a first aspect of the present invention includes a display region including a TFT layer provided with a plurality of transistors, a light-emitting element layer provided with a plurality of light-emitting elements, and a sealing layer, and a frame region surrounding the display region. The light-emitting element includes a first electrode, an edge cover provided with an opening that exposes the first electrode and configured to cover an end portion of the first electrode, a function layer, and a second electrode. The first hydrogen adsorption film is provided at an upper layer overlying the edge cover and in contact with the edge cover, and the first hydrogen adsorption film overlaps the transistor, at the adjacent light-emitting element, and is provided overlapping the first electrode of the adjacent light-emitting element, with the edge cover interposed therebetween, and spanning the adjacent light-emitting element.

In the display device according to a second aspect of the present invention, with respect to the first aspect described above, the first hydrogen adsorption film may be formed to span at least the adjacent light-emitting element of the same color.

In the display device according to a third aspect of the present invention, with respect to the first or second aspect described above, the first hydrogen adsorption film may be formed to have an opening between the opening of the edge cover and an edge of the first electrode.

In the display device according to a fourth aspect of the present invention, with respect to any one of the first to third aspects described above, the first hydrogen adsorption film may be formed to span the adjacent light-emitting element of a different color.

In the display device according to a fifth aspect of the present invention, with respect to the third aspect described above, the opening of the first hydrogen adsorption film may be formed to be larger than the opening of the edge cover.

In the display device according to a sixth aspect of the present invention, with respect to any one of the first to fifth aspects described above, the first hydrogen adsorption film may be formed in a straight line for the light-emitting elements of each of different colors.

In the display device according to a seventh aspect of the present invention, with respect to any one of the first to fifth aspects described above, the first hydrogen adsorption film may be formed in an island shape for each of the two adjacent light-emitting elements of the same color.

In the display device according to an eighth aspect of the present invention, with respect to any one of the first to seventh aspects described above, in the frame region, a second hydrogen adsorption film may surround the display region, may be formed overlapping the second electrode, and may be electrically connected to the second electrode.

In the display device according to a ninth aspect of the present invention, with respect to the eighth aspect described above, in a flattening film in the frame region, a trench may be formed surrounding the display region, and in the trench, a conductive film may be formed of the same material in the same layer as the first electrode, and the conductive film may be electrically connected to the second electrode via the second hydrogen adsorption film.

In the display device according to a tenth aspect of the present invention, with respect to the eighth or ninth aspect described above, in the frame region, a control circuit may be formed overlapping the second hydrogen adsorption film.

In the display device according to an eleventh aspect of the present invention, with respect to any one of the eighth to tenth aspects described above, the first hydrogen adsorption film and the second hydrogen adsorption film may not be electrically connected with each other.

In the display device according to a twelfth aspect of the present invention, with respect to any one of the first to eleventh aspects described above, in the display region, a first photospacer may be formed by the same material in the same layer as the edge cover, and the first hydrogen adsorption film may be formed on the first photospacer.

In the display device according to a thirteenth aspect of the present invention, with respect to any one of the eighth to eleventh aspects described above, in the frame region, a second photospacer may be formed by the same material in the same layer as the edge cover, and the second hydrogen adsorption film may be formed on the second photospacer.

In the display device according to a fourteenth aspect of the present invention, with respect to any one of the first to thirteenth aspects described above, the first hydrogen adsorption film may be formed of a hydrogen adsorption metal.

In the display device according to a fifteenth aspect of the present invention, with respect to any one of the eighth to eleventh aspects described above, the second hydrogen adsorption film may be formed of a hydrogen adsorption metal.

In the display device according to a sixteenth aspect of the present invention, with respect to the fourteenth or fifteenth aspect described above, the hydrogen adsorption metal may be one of Ti, Zr, Pd, and Mg.

In the display device according to a seventeenth aspect of the present invention, with respect to any one of the first to sixteenth aspects described above, a thickness of the first hydrogen adsorption film may be from 100 nm to 200 nm.

In the display device according to an eighteenth aspect of the present invention, with respect to any one of the eighth to eleventh aspects described above, a thickness of the second hydrogen adsorption film may be from 100 nm to 200 nm.

In the display device according to a nineteenth aspect of the present invention, with respect to any one of the first to eighteenth aspects described above, the transistor in the TFT layer may be formed using an oxide semiconductor.

In the display device according to a twentieth aspect of the present invention, with respect to any one of the first to nineteenth aspects described above, the transistor in the TFT layer may be a drive transistor.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in the embodiments.

### REFERENCE SIGNS LIST

2 Display device
4 TFT layer
5 Light-emitting element layer
6 Sealing layer
21 Flattening film
21t Trench
22 First electrode
22A Conductive film
23 Edge cover
23c, 29c Opening
24 Function layer
25 Second electrode
29 First hydrogen adsorption film
30 Second hydrogen adsorption film
DTM Control circuit
DA Display region
NA Frame region
PS1 First photospacer
PS2 Second photospacer
Tr Transistor
Tra Drive transistor

1: A display device comprising:
a display region including a TFT layer provided with a plurality of transistors, a light-emitting element layer provided with a plurality of light-emitting elements, and a sealing layer; and
a frame region surrounding the display region,
wherein the light-emitting element includes a first electrode, an edge cover provided with an opening that exposes the first electrode and configured to cover an end portion of the first electrode, a function layer, and a second electrode,
a first hydrogen adsorption film is provided at an upper layer overlying the edge cover and in contact with the edge cover, and
the first hydrogen adsorption film overlaps the transistor, at the adjacent light-emitting element, and is provided overlapping the first electrode of the adjacent light-emitting element, with the edge cover interposed therebetween, and spanning the adjacent light-emitting element.

2: The display device according to claim 1,
wherein the first hydrogen adsorption film is formed to span at least the adjacent light-emitting element of a same color.

3: The display device according to claim 1,
wherein the first hydrogen adsorption film is formed to have an opening between the opening of the edge cover and an edge of the first electrode.

4: The display device according to claim 1,
wherein the first hydrogen adsorption film is formed to span the adjacent light-emitting element of a different color.

5: The display device according to claim 3,
wherein the opening of the first hydrogen adsorption film is formed to be larger than the opening of the edge cover.

6: The display device according to claim 1,
wherein the first hydrogen adsorption film is formed in a straight line for the light-emitting elements of each of different colors.

7: The display device according to claim 1,
wherein the first hydrogen adsorption film is formed in an island shape for each of the two adjacent light-emitting elements of the same color.

8: The display device according to claim 1,
wherein, in the frame region, a second hydrogen adsorption film surrounds the display region, is formed overlapping the second electrode, and is electrically connected to the second electrode.

9: The display device according to claim 8,
wherein, in a flattening film in the frame region, a trench is formed surrounding the display region, and
in the trench, a conductive film is formed of a same material in a same layer as the first electrode, and
the conductive film is electrically connected to the second electrode via the second hydrogen adsorption film.

10: The display device according to claim 8,
wherein, in the frame region, a control circuit is formed overlapping the second hydrogen adsorption film.

11: The display device according to claim 8,
wherein the first hydrogen adsorption film and the second hydrogen adsorption film are not electrically connected with each other.

12: The display device according to claim 1,
wherein, in the display region, a first photospacer is formed by a same material in a same layer as the edge cover, and the first hydrogen adsorption film is formed on the first photospacer.

13: The display device according to claim 8,
wherein, in the frame region, a second photospacer is formed by a same material in a same layer as the edge cover, and the second hydrogen adsorption film is formed on the second photospacer.

14: The display device according to claim 1,
wherein the first hydrogen adsorption film is formed of a hydrogen adsorption metal.

15: The display device according to claim 8,
wherein the second hydrogen adsorption film is formed of a hydrogen adsorption metal.

16: The display device according to claim 14,
wherein the hydrogen adsorption metal is one of Ti, Zr, Pd, and Mg.

17: The display device according to claim 1,
wherein a thickness of the first hydrogen adsorption film is from 100 nm to 200 nm.

18: The display device according to claim 8,
wherein a thickness of the second hydrogen adsorption film is from 100 nm to 200 nm.

19: The display device according to claim 1,
wherein the transistor in the TFT layer is formed using an oxide semiconductor.

20: The display device according to claim 1,
wherein the transistor in the TFT layer is a drive transistor.
